(19) United States
(12) Patent Application Publication
(10) Pub. No.: US 2026/0129971 A1
(43) Pub. Date: May 7, 2026

(54) MULTI-FINGER SEMICONDUCTOR DEVICES WITH DUMMY GATE STRUCTURES

(71) Applicant: GlobalFoundries U.S. Inc., Malta, NY (US)

(72) Inventors: Kaustubh Shanbhag, Slingerlands, NY (US); Vibhor Jain, Clifton Park, NY (US); Judson Robert Holt, Ballston Lake, NY (US); Tamilmani Ethirajan, Guilderland, NY (US); Teng-Yin Lin, Clifton Park, NY (US)

(21) Appl. No.: 18/939,622

(22) Filed: Nov. 7, 2024

(51) Int. Cl. H01L 27/12; H01L 21/84; H01L 29/40; H01L 29/417; H01L 29/78

(52) U.S. Cl. CPC H10D 86/201; H10D 30/60; H10D 64/111; H10D 64/257; H10D 86/01

(57) ABSTRACT

The present disclosure relates to semiconductor structures and, more particularly, to multi-finger semiconductor devices with dummy gate structures and methods of manufacture. The structure includes: a plurality of active gate structures over a semiconductor substrate; a shared diffusion region in the semiconductor substrate between adjacent active gate structures of the plurality of gate structures; and a gate structure shorted to the shared diffusion region.

### BACKGROUND

The present disclosure relates to semiconductor structures and, more particularly, to multi-finger semiconductor devices with dummy gate structures and methods of manufacture.

A multi-finger layout of a transistor consists of splitting a gate structure into multiple parallel fingers. A multi-finger gate MOSFET is used in RF CMOS analog circuit designs due to the increased circuit performance. An advantage of this is that parasitic capacitances and gate resistance can be simultaneously reduced. The multi-finger gate MOSFET can also exhibit area savings on the silicon substrate, as diffusion regions (e.g., source or drain regions) can be shared amongst adjacent gate structures.

### SUMMARY

In an aspect of the disclosure, a structure comprises: a plurality of active gate structures over a semiconductor substrate; a shared diffusion region in the semiconductor substrate between adjacent active gate structures of the plurality of gate structures; and a gate structure shorted to the shared diffusion region.

In an aspect of the disclosure, a structure comprises: a plurality of active gate structures on a semiconductor substrate, the plurality of active gate structures each including a gate dielectric material and a gate electrode; a diffusion region shared amongst adjacent active gate structure of the plurality of gate structures; at least one gate structure comprising a gate electrode electrically connecting to the diffusion region; and contacts connecting to the diffusion region.

In an aspect of the disclosure, a method comprises: forming a plurality of active gate structures over a semiconductor substrate; forming a shared diffusion region in the semiconductor substrate between adjacent active gate structures of the plurality of gate structures; and forming a gate structure shorted to the shared diffusion region.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1A shows a top view of a structure and respective fabrication processes in accordance with aspects of the present disclosure.

FIG. 1B shows a cross-sectional view of the structure of FIG. 1A along lines “A”-“A”.

FIG. 2 shows a structure in accordance with additional aspects of the present disclosure.

FIG. 3 shows a structure in accordance with further aspects of the present disclosure.

FIG. 4A shows a top view of a structure in accordance with further aspects of the present disclosure.

FIG. 4B shows a cross-sectional view of the structure of FIG. 4A along lines “A”-“A”.

FIG. 4C shows a cross-sectional view of the structure of FIG. 4A along lines “B”-“B”.

FIG. 5A shows a top view of a structure in accordance with additional aspects of the present disclosure.

FIG. 5B shows a cross-sectional view of the structure of FIG. 5A along lines “A”-“A”.

FIG. 6 shows a structure with multiple dummy gate structures in a shared diffusion region in accordance with additional aspects of the present disclosure.

FIGS. 7A-7D show fabrication steps for manufacturing the structure of FIGS. 1A and 1B.

### DETAILED DESCRIPTION

The present disclosure relates to semiconductor structures and, more particularly, to multi-finger semiconductor devices with dummy gate structures and methods of manufacture. More specifically, the multi-finger semiconductor devices include dummy gate structures between active gate structures, with the dummy gate structures shorted to a shared drain region or source region of adjacent active gate structures. Advantageously, the multi-finger semiconductor devices with dummy gates structures will exhibit improved thermal performance (e.g., an increase in thermal resistance (R-values)), with increased contact density, a larger diffusion region and area savings.

The structures of the present disclosure can be manufactured in a number of ways using a number of different tools. In general, though, the methodologies and tools are used to form structures with dimensions in the micrometer and nanometer scale. The methodologies, i.e., technologies, employed to manufacture the structures of the present disclosure have been adopted from integrated circuit (IC) technology. For example, the structures are built on wafers and are realized in films of material patterned by photolithographic processes on the top of a wafer. In particular, the fabrication of the structures uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

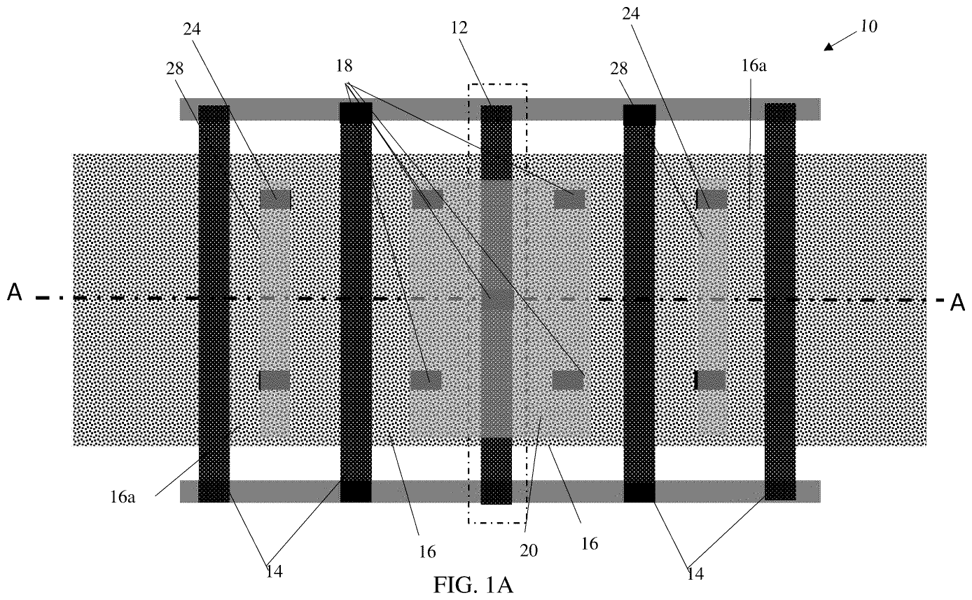

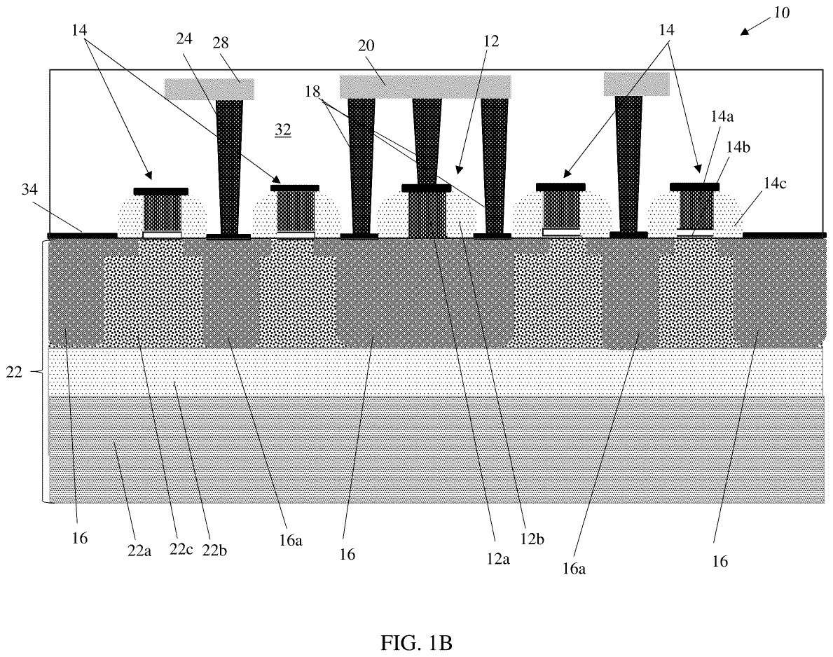

FIG. 1A shows a top view of a structure and respective fabrication processes in accordance with aspects of the present disclosure and FIG. 1B shows a cross-sectional view of the structure of FIG. 1A along lines “A”-“A”. More specifically and referring to both FIGS. 1A and 1B, in embodiments, the structure 10 includes a dummy gate structure 12 between adjacent active gate structures 14. The dummy gate structure 12 sits over and is electrically connected, e.g., electrically shorted, to a shared diffusion region 16 of the adjacent active gate structures 14. In embodiments, the shared diffusion region 16 may be a shared drain region or, alternatively, a shared source region for the adjacent active gate structures 14. In either layout, the dummy gate structure 12 is shorted to the shared diffusion region 16, with contacts 18 (via interconnect structures) connecting (e.g., electrically connecting) to the dummy gate structure 12 and the shared diffusion region 16 on both sides of the dummy gate structure 12. In this configuration, the dummy gate structure 12 and the additional contacts 18 will increase contact density and provide increased thermal resistance.

More specifically and still referring to FIG. 1B, the structure 10 includes a semiconductor substrate 22. The semiconductor substrate 22 may be semiconductor-on-insulator (SOI) technology. In the SOI technology, a handle substrate 22a and upper semiconductor substrate 22c may be composed of any suitable material including, but not limited to, Si, SiGe, SiGeC, SiC, GaAs, InAs, InP, and other III/V or II/VI compound semiconductors. In embodiments, the semiconductor substrate 22c is preferably a p-type semiconductor substrate with a suitable single crystallographic orientation (e.g., a (100), (110), (111), or (001) crystallographic orientation). In embodiments, the upper semiconductor substrate 22c may include a well as is known in the art, which is representatively shown by a different cross-hatching of the handle substrate 12a and the upper semiconductor substrate 12c.

The handle substrate 22a provides mechanical support to a buried insulator layer 22b and the upper semiconductor substrate 22c. The buried insulator layer 22b may include a dielectric material such as silicon dioxide, silicon nitride, silicon oxynitride, boron nitride or a combination thereof. In one preferred embodiment, the buried insulator layer 22b may be a buried oxide layer formed by a deposition process, such as chemical vapor deposition (CVD), plasma enhanced chemical vapor deposition CVD (PECVD) or physical vapor deposition (PVD), or a thermal growth process as is known in the art such that no further explanation is required herein for a complete understanding of the present disclosure.

As shown in FIGS. 1A and 1B, diffusion regions 16, 16a may be provided within the upper semiconductor substrate 22c, e.g., within the well, extending to the buried insulator layer 22b. In embodiments, the diffusion region 16a may be a source region for the active gate structures 14 and the shared diffusion region 16 may be a shared drain region. In alternative embodiments, the diffusion region 16a may be a drain region for the active gate structures 14 and the shared diffusion region 16 may be a shared source region. In either configuration, the dummy gate structure 12 is shorted directly to the shared diffusion region 16.

In either configuration, the diffusion regions 16, 16a are formed by an ion implantation process. For example, patterned implantation masks may be used to define selected areas exposed for the implantation, e.g., diffusion regions 16, 16a. The implantation masks may include a layer of a light-sensitive material, such as an organic photoresist, applied by a spin coating process, pre-baked, exposed to light projected through a photomask, baked after exposure, and developed with a chemical developer. The implantation masks have a thickness and stopping power sufficient to block the masked area against receiving a dose of the implanted ions. Depending on the device type, the diffusion regions 16, 16a may be p+ doped or n+ doped. For example, p-type dopants may be, e.g., boron; whereas, n-type dopants may be, e.g., Arsenic (As), Phosphorus (P) and Antimony (Sb), among other suitable examples.

The active gate structures 14 and the dummy gate structure 12 may be formed on the upper semiconductor substrate 22c. In embodiments, the dummy gate structure 12 may be formed over and in contact with the shared diffusion region 16; whereas the active gate structures 14 may be adjacent to each of the respective diffusion regions 16, 16a. In embodiments, the dummy gate structure 12 may be shorted directly to the shared diffusion region 16 by completely or partially removing a gate dielectric material from underneath the dummy gate structure 12. In this way, the gate electrode sits directly on and is shorted to the shared diffusion region 16, providing an increased contact density and thermal performance.

For example, as shown in FIG. 1B, the active gate structures 14 include a gate dielectric material 14a, a gate electrode 14b and sidewall spacers 14c. In this configuration, the gate dielectric material 14a sits directly on the upper semiconductor substrate 22c, which isolates the gate electrode 14b from the upper semiconductor substrate 22c and the diffusion regions 16, 16a. In contrast, the dummy gate structure 12 includes a gate electrode 12a and sidewall spacers 12b, with the gate electrode 12a sitting directly on the upper semiconductor substrate 22c and, more specifically, the shared diffusion region 16. In this way, the dummy gate structure 12 may be shorted directly to the shared diffusion region 16. Accordingly, the dummy gate structure 12 can now be used as a heat sink, thereby increasing thermal performance of the device.

In embodiments, the gate dielectric material 14a may be a high-k or low-k dielectric material as is known in the art. For example, a high-k dielectric material may be a hafnium based material and a low-k dielectric material may be oxide. The gate electrode material 12a, 14b may be a polysilicon material. The sidewall spacers 12b, 14c formed on the sidewalls on the gate structures 12, 14 may be multiple layers of oxide and/or nitride material or combinations thereof as is known in the art.

Although not critical to the understanding of the present disclosure, the dummy gate structure 12 and the active gate structures 14 can be fabricated using conventional CMOS processes. In embodiments, the gate structures 12, 14 may exhibit a minimum gate pitch; although other dimensions are contemplated herein. Also, as in each of the embodiments, the gate structures 12, 14 may parallel gate structures in a multi-finger layout.

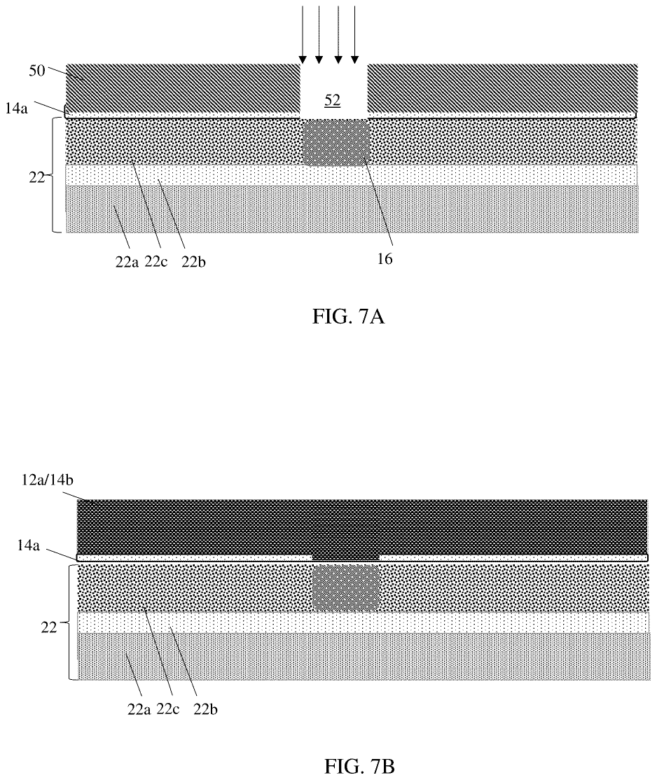

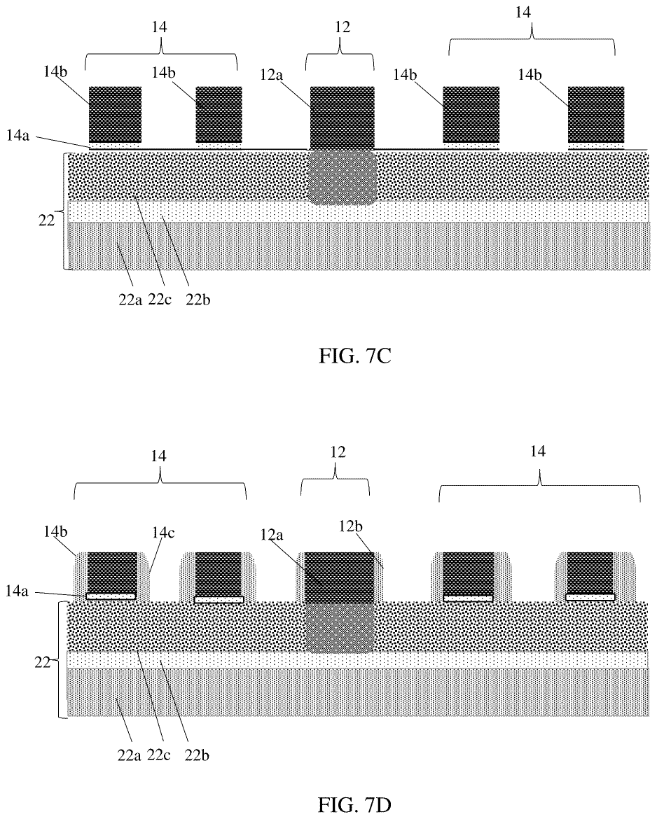

As to the active gate structures 14, in the standard CMOS processing the gate dielectric material 14a and gate electrode material 14b, e.g., polysilicon material, are formed, e.g., deposited, on the upper semiconductor substrate 22c, followed by a patterning process. An insulator material such as nitride or oxide can be deposited on the patterned materials, followed by an anisotropic etching process to form the sidewall structures 14c. The gate dielectric material 14a may be deposited by a conventional CVD process or, alternatively, an atomic layer deposition (ALD) or plasma-enhanced CVD (PECVD) as other examples. The material of the sidewall structures 14c and the gate electrode material 12d may be deposited by a CVD process, with the sidewall structures 14c being patterned by an anisotropic etching process as is known in the art. The dummy gate structures 12 may be formed in a similar manner, with the exception of the gate dielectric material being removed, e.g., etched, prior to the deposition of gate electrode as described in more detail with respect to FIGS. 7A-7D.

FIG. 1B shows silicide contacts 34 provided in contact with the diffusion regions 16, 16a, the gate electrode 12a of the dummy gate structure 12 and the gate electrodes 14a of the active gate structures 14. As should be understood by those of skill in the art, the silicide process begins with deposition of a thin transition metal layer, e.g., nickel, cobalt or titanium, over fully formed and patterned semiconductor material (e.g., diffusion regions and gate electrodes). After deposition of the material, the structure is heated allowing the transition metal to react with exposed silicon (or other semiconductor material as described herein) in the active regions of the semiconductor device (e.g., diffusion regions and gate electrodes) forming a low-resistance transition metal silicide. Following the reaction, any remaining transition metal is removed by chemical etching, leaving silicide contacts 34.

As shown further in FIG. 1B, via interconnect structures (e.g., contacts) 18, 24 may be formed to contact the silicide contacts 34, e.g., on the gate electrodes 12a, 14b and diffusion regions 16, 16a. The via interconnect structures 18, 24 may be any conductive material used in fabricating of contacts, e.g., tungsten, TiN, TaN, etc. As should be understood by those of skill in the art, the contacts 18 (via interconnect structures) connecting to the dummy gate structure 12 and the shared diffusion region 16 may be aligned or offset from one another.

The via interconnect structures 18, 24 may be formed by conventional lithography, etching and deposition methods known to those of skill in the art. For example, a resist formed over an insulator material (interlevel dielectric material) 32 is exposed to energy (light) and developed utilizing a conventional resist developer to form a pattern (opening). An etching process with a selective chemistry, e.g., reactive ion etching (RIE), will be used to transfer the pattern from the photoresist layer to the insulator material 32 (e.g., interlevel dielectric material) to form one or more trenches in the insulator material 32. Following the resist removal by a conventional oxygen ashing process or other known stripants, conductive material can be deposited by any conventional deposition processes, e.g., chemical vapor deposition (CVD) processes. Any residual material on the surface of the insulator material 26 can be removed by conventional chemical mechanical polishing (CMP) processes.

FIGS. 1A and 1B show wiring structures 20, 28 provided in contact with the via interconnect structures 18, 24, formed by using conventional lithography, etching and deposition methods known to those of skill in the art and as already described herein. The wiring structures 18, 24 may be composed of any conventional conductive material used for wiring structures, e.g., copper, aluminum, etc. The wiring structure 20 connecting to the contacts 18 will electrically connect to the shared diffusion region 16, thereby increasing contact density.

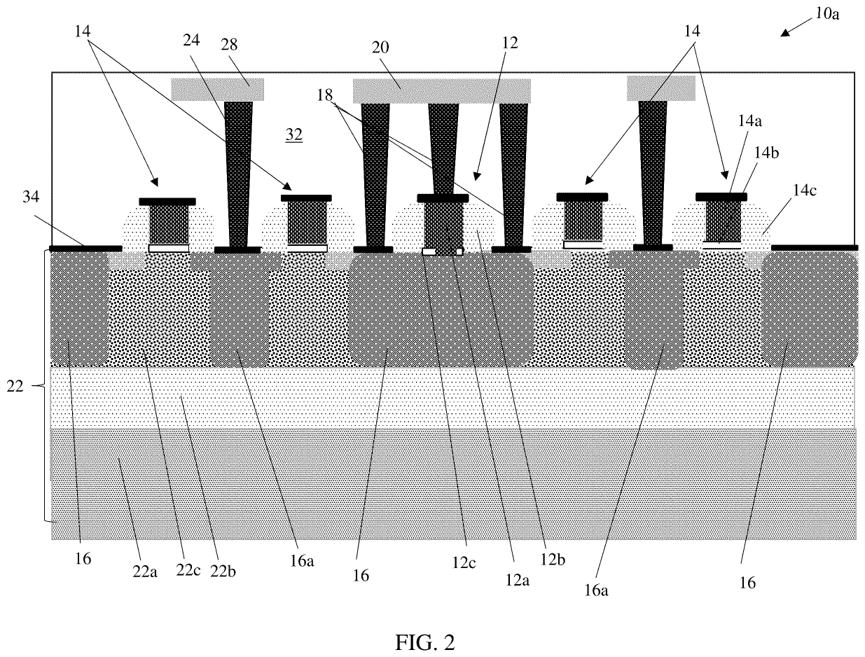

FIG. 2 shows an alternative structure in accordance with aspects of the present disclosure. In the structure 10a of FIG. 2, the dummy gate structure 12 includes gate dielectric material 12c partially underneath the gate electrode 12a. In this embodiment, the gate electrode 12a still contacts the shared diffusion region 16 and, as such, provides additional contact density and thermal performance to the device. It should be recognized by those of skill in the art that the dielectric material 12c partially underneath the gate electrode 12a may be implemented in any of the different embodiments described herein. The remaining features of the structure 10a of FIG. 2 are similar to the structure 10 of FIGS. 1A and 1B.

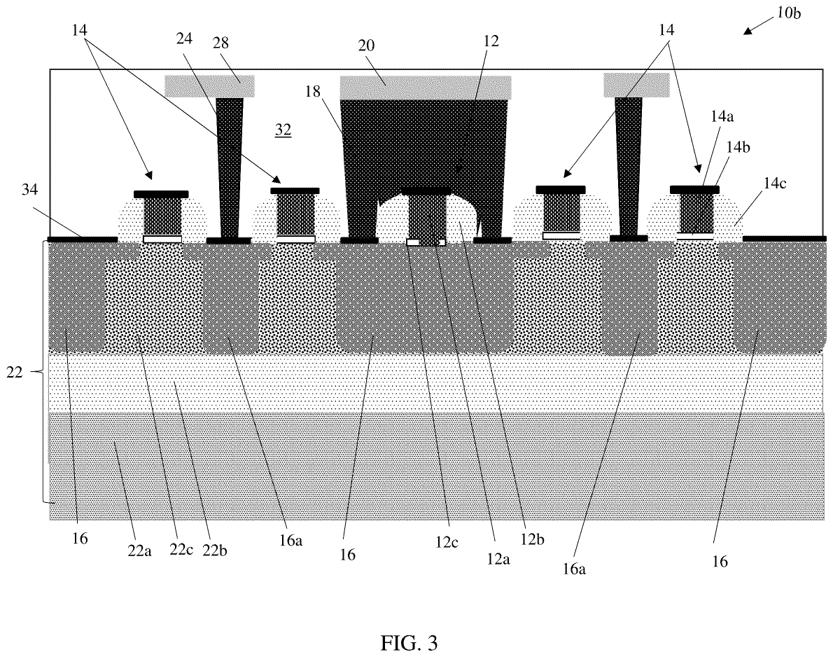

FIG. 3 shows an alternative structure in accordance with aspects of the present disclosure. In the structure 10b of FIG. 3, a single contact 18 may be provided to the dummy gate structure 12 and the shared diffusion region 16. In this embodiment, the contact 18 spans over the dummy gate structure 12 (e.g., gate electrode 12a and sidewall spacers 12b), and connects to the dummy gate structure 12 and both sides of the shared diffusion region 16. In this example, the single contact 18 provides a higher contact density than the structures 10, 10a. The remaining features of the structure 10b of FIG. 2 are similar to the structure 10 of FIGS. 1A and 1B.

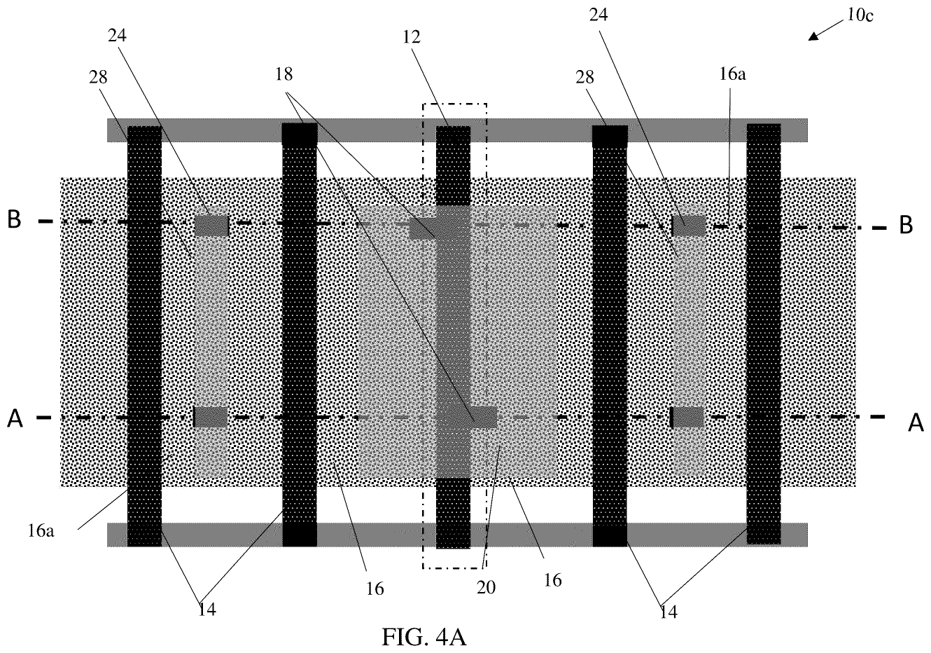

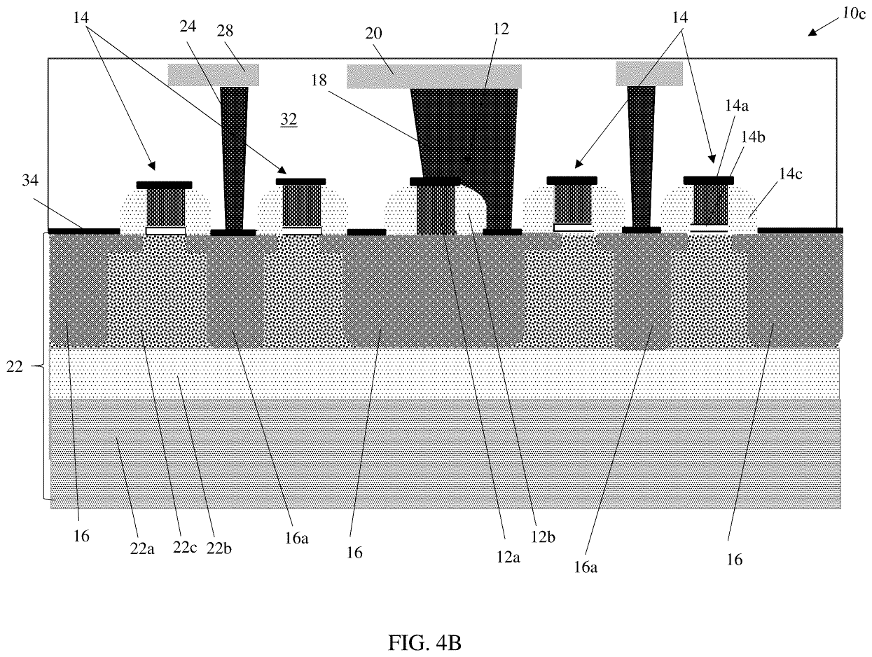

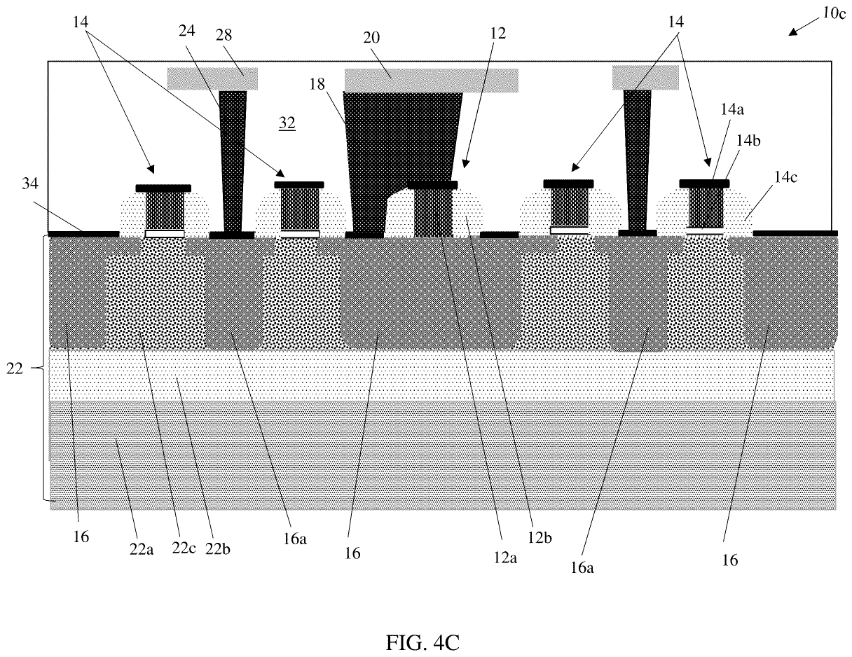

FIGS. 4A-4C show an alternative structure in accordance with aspects of the present disclosure. FIG. 4A shows a top view of the structure 10c; whereas FIG. 4B shows a cross-sectional view of the structure along lines “A”-“A” and FIG. 4C shows a cross-sectional view of the structure along lines “B”-“B”. In the structure 10c of FIGS. 4A-4C, the contacts 18 to the dummy gate structure 12 are offset along a length of the dummy gate structure 12. That is, each of the contacts 18 partially overlaps the dummy gate structure 12 and contacts the shared diffusion regions 16, e.g., on opposing sides, of dummy gate structure 12. The contacts 18 thus each make contact to the dummy gate structure 12 on opposing sides, in addition to opposing sides of the shared diffusion region 16. The remaining features of the structure 10c of FIG. 4 are similar to the structure 10 of FIGS. 1A and 1B.

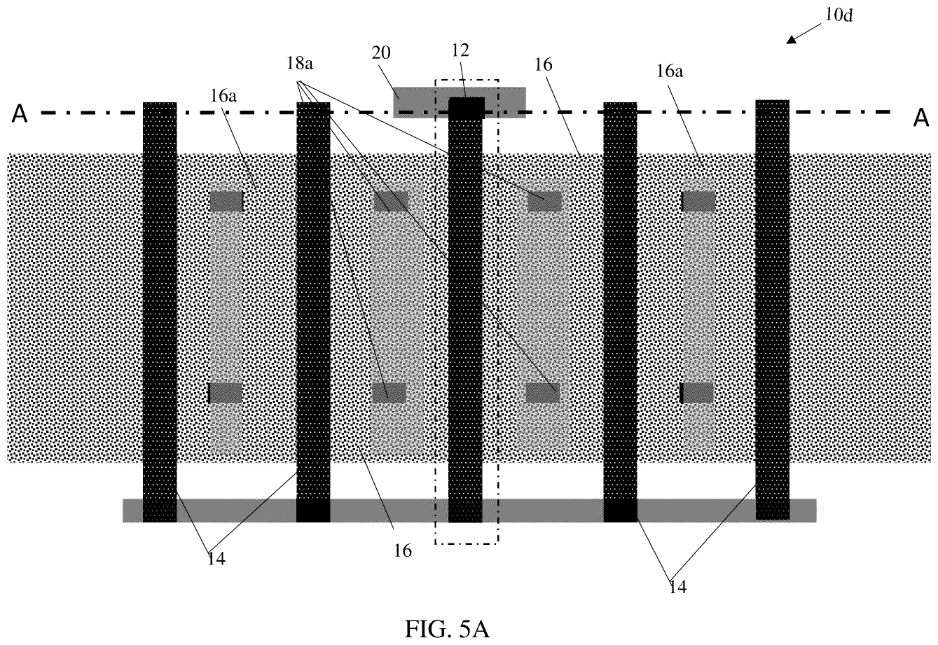

FIGS. 5A and 5B show an alternative structure in accordance with aspects of the present disclosure. In the structure 10d of FIGS. 5A and 5B, a single contact 18 is provided at an end of the dummy gate structure 12, with the shared diffusion region 16 having separate contacts 18a (as shown in FIG. 5A). In embodiments, the shared diffusion region 16 may be a source region which may be shallower than diffusion region 16a. In this layout, for example, it is contemplated in this embodiment that the dummy gate structure 12 may or may not be shorted to source terminals, e.g., wiring structures 29 or via interconnects 24 connecting thereto). A source shorted body contacted device will result by having the dummy gate structure 12 shorted. By not shorting the dummy gate structure 12 to the source terminals, a body node may be used to measure floating body potential. The doping of the dummy gate polysilicon may be of the same species as of the underlying well (e.g., well 22c) to create a low resistive ohmic contact to the body. In this context, the doping of the dummy gate structure 12 may be of the same or different species as that of the adjacent active gate structures 14. The remaining features of the structure 10d of FIGS. 5A and 5B are similar to the structure 10 of FIGS. 1A and 1B.

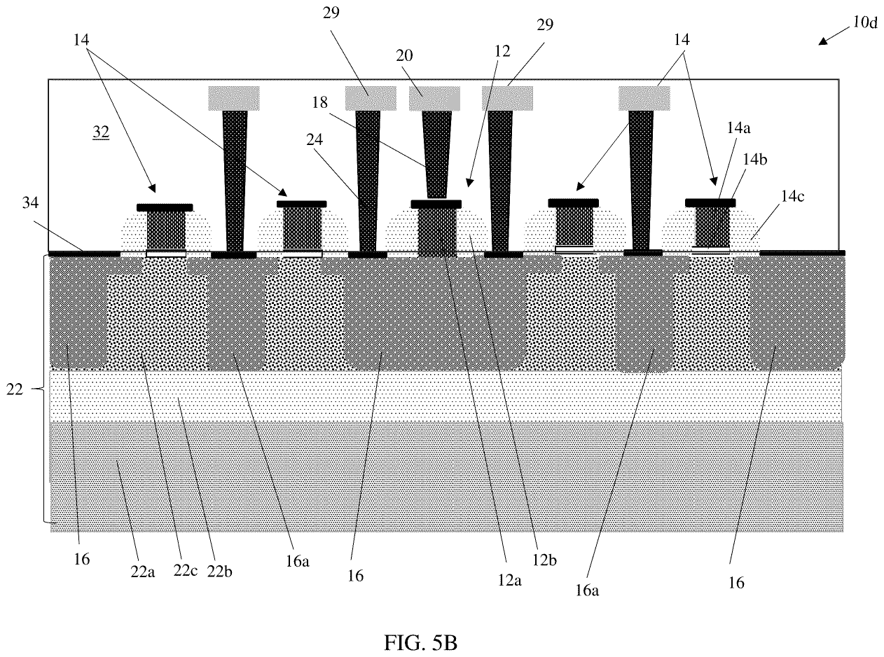

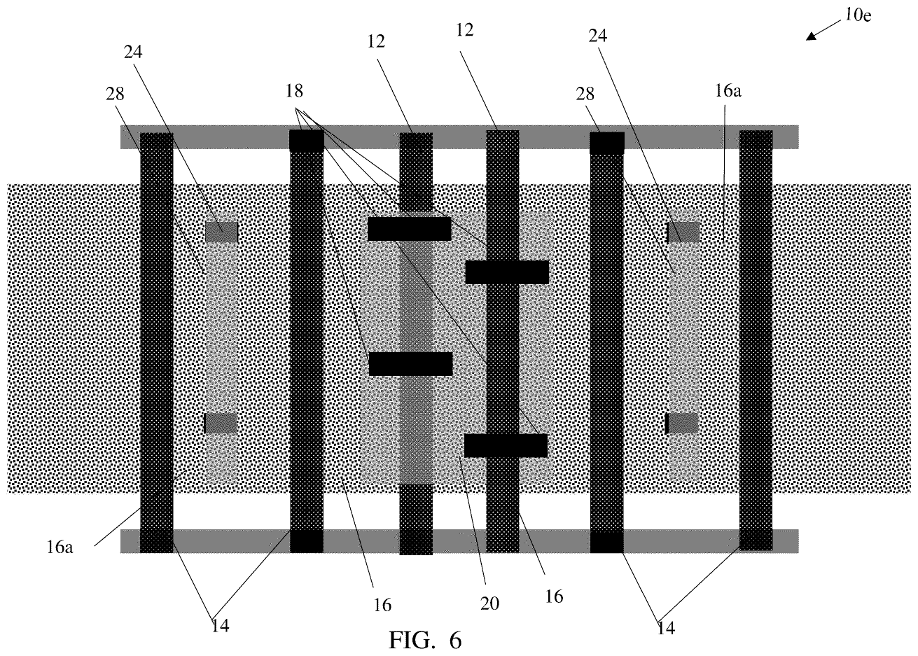

FIG. 6 shows a structure with multiple dummy gate structures in a shared diffusion region in accordance with additional aspects of the present disclosure. In particular, in the structure 10e of FIG. 6, two dummy gate structures 12 are shown in the shared diffusion region 16. The dummy gate structures 12 each have contacts 18 spanning over the dummy gate structures 12 and connecting to the shared drain region 16. A single wiring structure 20 connects to each of the contacts 18. It should be recognized by those of skill in the art that the contacts 18 may be any of the different layouts shown in FIGS. 1A-5B. it should also be recognized that the multiple dummy gate structures 12 may be two or more gate structures within the shared diffusion region 16. In this configuration, improved thermal performance (e.g., an increase in thermal resistance (R-values)), with increased contact density, a larger diffusion region and area savings can be achieved.

FIGS. 7A-7D show fabrication steps for manufacturing the structure of FIGS. 1A and 1B. Specifically, FIG. 7A shows formation of the gate dielectric material 14a on the semiconductor substrate 22, e.g., upper semiconductor substrate 22a. In embodiments, the gate dielectric material 14a may be a high-k or low-k dielectric material as already described herein. The gate dielectric material 14a may be deposited by a conventional CVD process or, alternatively, an atomic layer deposition (ALD) or plasma-enhanced CVD (PECVD) as other examples.

Still referring to FIG. 7A, a hardmask 50 may be formed over the gate dielectric material 14a. The hardmask 50 may be a nitride material deposited by a conventional CVD process. The hardmask 50 may be patterned to form an open 52 extending to and exposing the underlying gate dielectric material 14a. The opening 52 will correspond with the location of the yet to be formed dummy gate structure. The exposed gate dielectric material 14a may subsequently undergo an etching process through the opening 52 of the hardmask 50 to expose the underlying upper semiconductor substrate 22c. In this way, a portion of the gate dielectric material 14a is removed so that the dummy gate structure can sit directly on the upper semiconductor substrate 22c. The etching processes may be any conventional etching process, e.g., RIE, with selective etch chemistries for the hardmask 50 and the gate dielectric material 14a.

FIG. 7A shows the formation of the shared diffusion region 16. The shared diffusion region 16 may be formed by a conventional ion implantation process through the opening 52 as already described herein.

In FIG. 7B, the hardmask is removed and gate electrode material 12a, 14b may be formed over the gate dielectric material 14a and the exposed upper semiconductor substrate 22c. In embodiments, the gate electrode material 12a, 14b may be, e.g., polysilicon, which is blanket deposited over the gate dielectric material 14a and the exposed semiconductor substrate 22c. The blanket deposition process may be, for example, a CVD process.

In FIG. 7C, the gate electrode material 12a, 14b and the gate dielectric material 14a may be patterned using conventional lithography and etching processes, e.g., RIE. In this way, the gate electrode material 12a will form the dummy gate structure 12 directly on the exposed semiconductor substrate 22c, and the gate dielectric gate material 14a and the electrode material 14b will form the active gate structures 14. As shown in FIG. 7C, the gate electrode material 12a, e.g., dummy gate structure 12, is aligned with the diffusion region 16.

In FIG. 7D, the sidewall spacer 12b, 14c may be formed over the dummy gate structure 12 and the active gate structures 14. Prior to the spacer formation, the structure may undergo a reoxidation process to form oxide on the exposed surfaces. Thereafter, sidewall spacer material, e.g., oxide, nitride and combinations thereof, may be blanket deposited on the structure, followed by an anisotropic etching process. The sidewall spacer material may be deposited by a conventional CVD process.

Referring again to FIGS. 1A and 1B, source and drain extensions may be formed by halo or other implantation processes as is known in the art. Thereafter, the silicide contacts 34, interconnect via structures 18, 24 and wiring structures 20, 28 may be formed by conventional processes as already described herein.

The structures can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a plurality of active gate structures over a semiconductor substrate;
a shared diffusion region in the semiconductor substrate between adjacent active gate structures of the plurality of gate structures; and
a gate structure shorted to the shared diffusion region.

2. The structure of claim 1, wherein the gate structure comprises a gate electrode contacting the shared diffusion region.

3. The structure of claim 2, wherein the gate structure is devoid of a gate dielectric material between the gate electrode and the shared diffusion region.

4. The structure of claim 2, further comprising a gate dielectric material between a portion of the gate electrode and the shared diffusion region.

5. The structure of claim 1, wherein the shared diffusion region is a shared drain region.

6. The structure of claim 2, further comprising a plurality of contacts connecting to the gate electrode of the gate structure and the shared diffusion region on opposing sides of the gate structure, and a wiring structure connecting to the plurality of contacts.

7. The structure of claim 2, further comprising a contact which spans over the gate structure and connecting to the gate electrode of the gate structure and the shared diffusion region on opposing sides of the gate structure.

8. The structure of claim 2, further comprising a plurality of contacts each of which partially span over the gate structure, a first contact connecting to the gate electrode of the gate structure on a first side and the shared diffusion region adjacent to the first side and a second contact connecting to the gate electrode of the gate structure on a second side of the shared diffusion region adjacent to the second side, and a wiring structure connecting to the plurality of contacts.

9. The structure of claim 8, wherein the first contact and the second contact are located at different locations along a length of the gate structure.

10. The structure of claim 1, further comprising a second gate structure shorted to and over the shared diffusion region.

11. The structure of claim 1, further comprising contacts on opposing sides of the gate structure and connecting to the shared diffusion region.

12. The structure of claim 1, wherein the shared diffusion region is shallow than an adjacent diffusion region.

13. A structure comprising:
a plurality of active gate structures on a semiconductor substrate, the plurality of active gate structures each including a gate dielectric material and a gate electrode;
a diffusion region shared amongst adjacent active gate structure of the plurality of gate structures;
at least one gate structure comprising a gate electrode electrically connecting to the diffusion region; and
contacts connecting to the diffusion region.

14. The structure of claim 13, wherein the at least one gate structure comprises a gate dielectric material under a portion of the gate electrode.

15. The structure of claim 13, further comprising a contact spanning over the gate structure and electrically connecting to the gate electrode and opposing sides of the diffusion region.

16. The structure of claim 13, further comprising a plurality of contacts connecting to the gate electrode of the gate structure and opposing sides of the diffusion region, with a common wiring structuring connecting to the plurality of contacts.

17. The structure of claim 16, wherein the plurality of contacts comprising a first contact spanning partially over and connecting to a first side of the gate electrode of the gate structure and a first side of the diffusion region and a second contact spanning partially over and connecting to a second side of the gate electrode of the gate structure and a second side of the diffusion region.

18. The structure of claim 13, wherein the plurality of contacts comprising a first contact electrically connecting to a diffusion region on a first side of the gate structure and a second contact electrically connecting to the diffusion region on a second side of the gate structure.

19. The structure of claim 13, wherein the plurality of active gate structures and the gate structure are parallel finger gate structures.

20. A method comprising:
forming a plurality of active gate structures over a semiconductor substrate;
forming a shared diffusion region in the semiconductor substrate between adjacent active gate structures of the plurality of gate structures; and
forming a gate structure shorted to the shared diffusion region
